(19) United States
(12) Patent Application Publication
(10) Pub. No.: US 2010/0116309 A1
(43) Pub. Date: May 13, 2010

(54) THERMOELECTRIC MATERIALS

(75) Inventors: Su Dong Park, Changwon-si (KR); Hee Woong Lee, Changwon-si (KR); Bong Seo Kim, Changwon-si (KR); Min Wook Oh, Changwon-si (KR)

Correspondence Address: HYUN JONG PARK;Park & Associates IP Law LLC, 265 Bic Drive, Suite 106, Milford, CT, 06461, US

(73) Assignee: Korea Electrotechnology Research Institute, Changwon-si (KR)

(21) Appl. No.: 12/344,406

(22) Filed: Dec. 26, 2008

(30) Foreign Application Priority Data
Nov. 13, 2008 (KR) 10-2008-0112763

(51) Int. Cl. H01L 35/20

(52) U.S. Cl. 136/239; 136/241; 136/240

(57) ABSTRACT

Disclosed herein is a thermoelectric material for intermediate- and low-temperature applications, in which any one or a mixture of two or more selected from among La, Sc and MM is added to a Ag-containing metallic thermoelectric material or semiconductor thermoelectric material. The thermoelectric material has a low thermal diffusivity, a high Seebeck coefficient, a low specific resistivity, a high power factor and a low thermal conductivity, and thus has a high dimensionless figure of merit, thus showing very excellent thermoelectric properties. The thermoelectric material provide thermoelectric sensors having high sensitivity and low noise and, in addition, is widely used as a thermoelectric material for intermediate- and low-temperature applications, because it shows excellent thermoelectric performance in the intermediate- and low-temperature range.

### FIELD OF THE INVENTION

The present invention relates to a thermoelectric material, and more particularly to a thermoelectric material for intermediate- and low-temperature applications, which has excellent thermoelectric performance and in which any one or a mixture of two or more selected from among La, Sc and MM is added to a metallic or semiconductor thermoelectric material.

### BACKGROUND OF THE INVENTION

In general, thermoelectric conversion technology includes the two application fields of thermoelectric cooling and thermoelectric power generation. Thermoelectric cooling is explained by the principle of the Peltier effect in which heat is transferred from one end to another end of a thermoelectric material when electric current is applied, and thermoelectric power generation is explained by the principle of the Seebeck effect in which electromotive force is generated when the temperature difference is applied across the both ends of a thermoelectric material. Thermoelectric cooling has been developed in terms of the cooling effect rather than the utilization of energy, and thus has been widely studied in many application fields, whereas thermoelectric power generation has been little studied because it aims at the generation of electricity and cannot secure competitiveness with existing power generation methods in terms of economic efficiency and fields of application.

The thermoelectric performance of thermoelectric materials for such thermoelectric power generation and thermoelectric cooling is determined by physical properties including the thermoelectromotive force (V), Seebeck coefficient (α), Peltier coefficient (π), Thomson coefficient (τ), Nernst coefficient (Q), Ettingshausen coefficient (P), electrical conductivity (σ), powder factor (PF), figure of merit (Z), dimensionless figure of merit (ZT=α 2 σT/κ wherein T is absolute temperature), thermal conductivity (κ), Lorentz ratio (L), electric resistivity (ρ), etc.

Particularly, the dimensionless figure of merit (ZT) is an important factor determining thermoelectric conversion efficiency, and when a thermoelectric element is manufactured using a thermoelectric material having a high figure of merit (Z=α 2 σ/κ), it can have an increased efficiency of cooling and powder generation.

Accordingly, it is particularly preferable to use a thermoelectric material having a high Seebeck coefficient (α) and high electrical conductivity, and thus a high power factor (PF=α 2 σ). It is most preferable to use a thermoelectric material having a low thermal conductivity (κ) in addition to the above-mentioned preferred properties. Moreover, it is preferable to use a thermoelectric material having a high Seebeck coefficient (α) together with a high ratio of electrical conductivity to thermal conductivity, σ/κ (=1/TL; mainly in the case of metals).

Thermoelectric materials include metallic thermoelectric materials represented by Bi and semiconductor thermoelectric materials represented by Si. Recently, semiconductor thermopiles having Seebeck coefficients higher that the metal-based materials have been mainly used; however, in fields requiring stability, metallic thermopiles are mainly used.

Such metallic thermopiles have an advantage of low noise due to low resistivity. However, they have low sensitivity due to a low Seebeck coefficient. For example, in Cu which has a Seebeck coefficient of almost zero, electromotive force generation as a result of temperature difference does not occur. Among metallic materials, Bi is used as a thermoelectric material due to its low thermal conductivity and high Seebeck coefficient.

Metallic thermoelectric materials which are mainly used in the prior art include Bi—Ag, Cu-constantan, Bi—Bi/Sn alloy, BiTe/BiSbTe, etc. Such metallic materials have a low thermal conductivity and a relatively high Seebeck coefficient compared to those of other metallic materials, but they have high resistivity, and thus have problems in that they have low sensitivity and cause high noise when they are used in thermosensors and the like.

In addition, prior thermoelectric materials are mainly used at low temperatures (temperatures below 100° C.) and have a shortcoming in that they have deteriorated thermoelectric performance at intermediate temperatures (100-300° C.).

### SUMMARY OF THE INVENTION

The present It is an object of the present invention to provide a thermoelectric material for intermediate- and low-temperature applications, which has excellent thermoelectric performance and in which any one or a mixture selected from among two or more of La, Sc and MM is added to a metallic or semiconductor thermoelectric material.

To achieve the above object, the present invention provides a thermoelectric material for intermediate- and low-temperature applications, including a Ag-containing metallic thermoelectric material or semiconductor thermoelectric material and any one or a mixture of two or more selected from among La, Sc and MM.

In the present invention, the metallic thermoelectric material may be a chalcogenide-based thermoelectric material, and preferably a Bi- or Pb-based thermoelectric material. The chalcogenide-based thermoelectric material may further include any one or a mixture of two or more selected from among Fe, Cu, Ni, Al, Au, Pt, Cr, Zn and Sn.

Also, the semiconductor thermoelectric material may be a Si-based thermoelectric material.

### BRIEF DESCRIPTION OF THE DRAWINGS

The above and other objects, features and advantages of the present invention will be more clearly understood from the following detailed description taken in conjunction with the accompanying drawings, in which:

FIG. 1 shows the thermal diffusivity of a thermoelectric material according to an embodiment of the present invention;

FIG. 2 shows the Seebeck coefficient of a thermoelectric material according to an embodiment of the present invention;

FIG. 3 shows the specific resistivity of a thermoelectric material according to an embodiment of the present invention;

FIG. 4 shows the power factor of a thermoelectric material according to an embodiment of the present invention;

FIG. 5 shows the thermal conductivity of a thermoelectric material according to an embodiment of the present invention; and

FIG. 6 shows the dimensionless figure of merit of a thermoelectric material according to an embodiment of the present invention.

### DETAILED DESCRIPTION OF THE INVENTION

The present invention relates to a thermoelectric material for intermediate- and low-temperature applications, which is used for thermoelectric cooling and thermoelectric power generation, and more particularly to a thermoelectric material for intermediate- and low-temperature applications, in which a specific component is added to a metallic or semiconductor thermoelectric material, such that it may be used at intermediate and low temperatures. As used herein, the term “intermediate- and low-temperature applications” means that the thermoelectric material has excellent thermoelectric performance not only at low temperatures of less than 100° C., but also at intermediate temperatures of about 100-300° C.

The metallic thermoelectric material is a chalcogenide-based thermoelectric material, preferably a thermoelectric material in which a Group-6 (VIb) element is added to a conventional Bi- or Pb-based thermoelectric material, and more preferably a thermoelectric material in which the semiconductor material Sb is added to Bi₂Te₃, PbTe, Bi₂Te₃, PbTe or the like. The semiconductor thermoelectric material is a Si-based thermoelectric material such as Si—Ge. It is known that the addition of Ag to such thermoelectric materials improves the thermoelectric performance of the thermoelectric materials. In addition, any one or a mixture of two or more selected from among Fe, Cu, Ni, Al, Au, Pt, Cr, Zn and Sn may be added to the chalcogenide-based thermoelectric material in order to further improve its thermoelectric performance.

In a preferred embodiment of the present invention, a BiSbTe-based thermoelectric material which is one of the above-described metallic thermoelectric materials will now be described.

The BiSbTe-based thermoelectric material according to the present invention is obtained by preparing a (Bi_{0.25}Sb_{0.75})₂(Te₁₋ₓAₓ)₃-Ag alloy, melting the alloy at 900-1000° C. for 9-12 hours, calcining the melted alloy at 280-320° C. for 5-7 hours, subjecting the calcined alloy to a hot pressing process at 350-450° C. for 20-40 minutes at 180-220 MPa, and then cutting the alloy with a wire. Herein, A is La, Sc, MM (misch metal; an alloy of cerium-group elements), or a mixture of two or more thereof.

More specifically, the (Bi_{0.25}Sb_{0.75})₂(Te₁₋ₓAₓ)₃-Ag alloy is formed either by powdering oxides corresponding to the elements of the alloy and adding Ag to the powder or by mixing powders of the respective elements with each other at a suitable weight ratio. Herein, A is a mixture of La and Sc, Ag is used in an amount of 0.5 wt % based on the total weight of the alloy, La is used in an amount of 0.05 wt %, and Sc is used in an amount of 0.1 wt %.

The (Bi_{0.25}Sb_{0.75})₂(Te₁₋ₓ(La,Sc)ₓ)₃-Ag alloy thus formed is melted in a quartz crucible at 960° C. (at a heating rate of 10° C./min) for 10 hours, and then naturally cooled. In this state, the alloy is calcined at 300° C. (at a heating rate of 10° C./min) for 6 hours, and then naturally cooled. Then, the alloy is subjected to a hot pressing process at 400° C. (at a heating rate of 10° C./min) at a pressure of 200 MPa for 30 minutes and naturally cooled. Then, the alloy is cut into a predetermined shape by a wire cutting machine, thus preparing a thermoelectric material.

Test results for the performance of the thermoelectric material (Bi_{0.25}Sb_{0.75})₂(Te₁₋ₓ(La,Sc)ₓ)₃-Ag (La: 0.05 wt %, Sc: 0.2 wt %, and Ag: 0.5 wt %)) will now be described. In a comparative example, (Bi_{0.25}Sb_{0.75})₂Te₃ and (Bi_{0.25}Sb_{0.75})₂Te₃—Ag(0.5 wt %) were prepared and tested. The tested properties of the thermoelectric materials are thermal diffusivity, Seebeck coefficient, specific resistivity, power factor, thermal conductivity, and the dimensionless figure of merit (ZT).

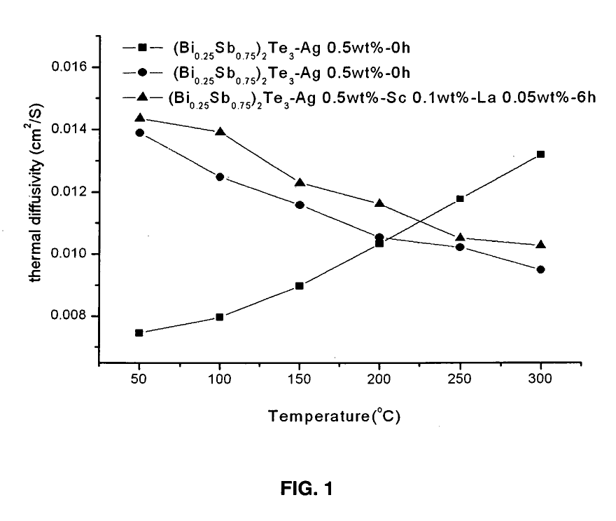

First, the thermal diffusivities of the thermoelectric materials according to the present invention and the comparative example were tested. As may be seen in FIG. 1, the thermoelectric material of the present invention showed a decrease in thermal diffusivity with increasing temperature and showed excellent thermoelectric performance in the intermediate temperature region, unlike the comparative example (Bi_{0.25}Sb_{0.75})₂Te₃.

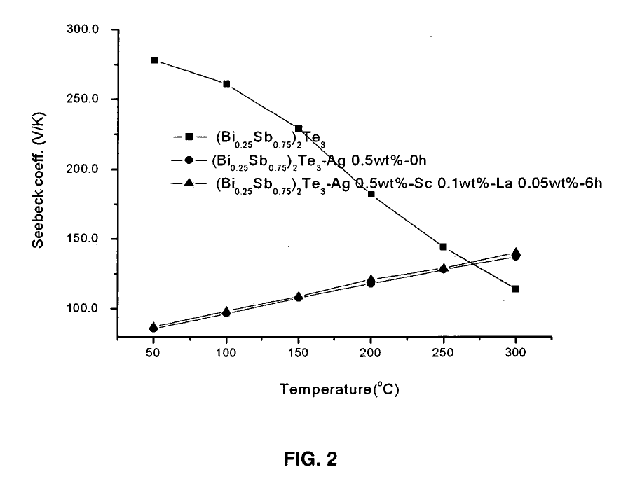

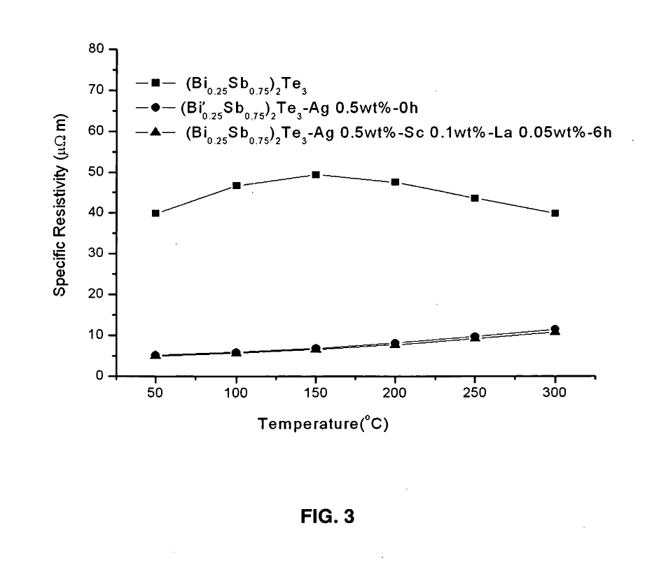

As shown in FIG. 2, the Seebeck coefficient of the thermoelectric material according to the present invention was significantly lower than that of the comparative example (Bi_{0.25}Sb_{0.75})₂Te₃ over the entire temperature range. As shown in FIG. 3, the specific resistivity of the thermoelectric material according to the present invention was lower than that of the comparative example over the entire temperature range.

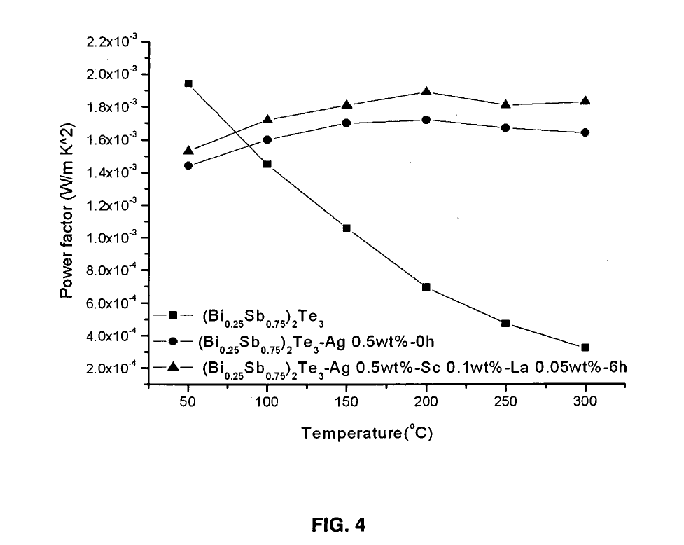

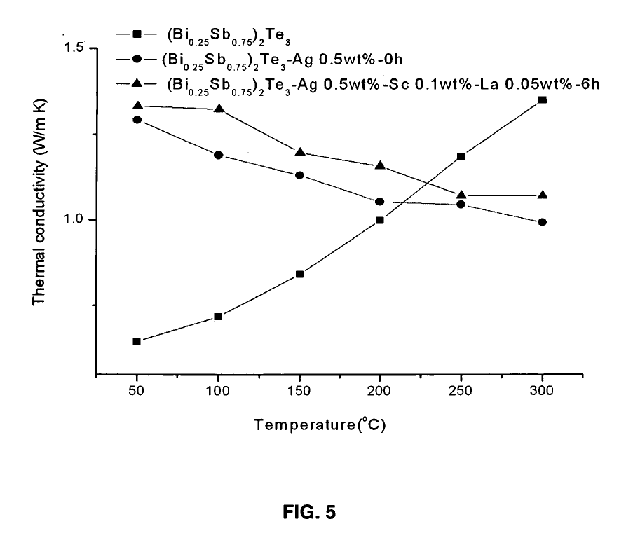

As shown in FIG. 4, the power factor of the thermoelectric material according to the present invention was higher than that of the comparative example (Bi_{0.25}Sb_{0.75})₂Te₃, particularly in the intermediate temperature range. As may be seen in FIG. 5, the thermal conductivity of the thermoelectric material according to the present invention decreased with increasing temperature, unlike the comparative example (Bi_{0.25}Sb_{0.75})₂Te₃, and showed a low value, particularly in the intermediate temperature range.

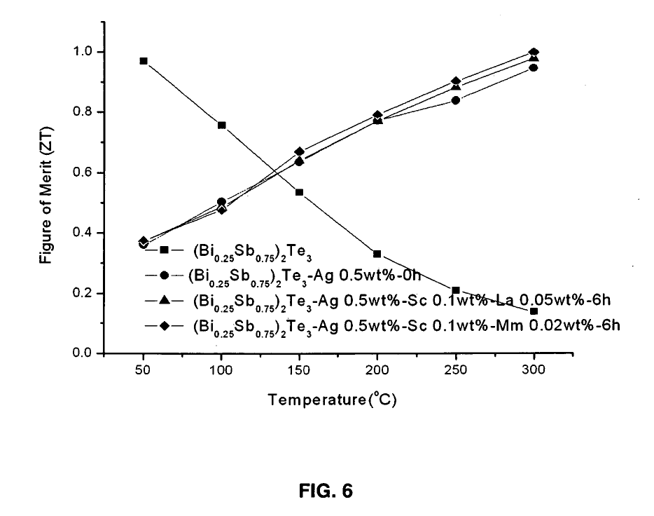

As shown in FIG. 6, the dimensionless figure of merit (ZT) calculated based on the above data for the thermoelectric material of the present invention was higher than that of the comparative example (Bi_{0.25}Sb_{0.75})₂Te₃ in the intermediate temperature region.

Thus, the thermoelectric material according to the present invention had a low thermal diffusivity, a high Seebeck coefficient, a low specific resistivity, a high power factor and a low thermal conductivity over the entire temperature range or in the intermediate temperature range, and thus had a high dimensionless figure of merit. This suggests that the thermoelectric material of the present invention shows very excellent thermoelectric properties. Accordingly, the thermoelectric material of the present invention can provide thermoelectric sensors having high sensitivity and low noise and, in addition, may be widely used as a thermoelectric power generation material for intermediate- and low-temperature applications, because it shows excellent thermoelectric performance, particularly in the intermediate temperature range.

Although the preferred embodiment of the present invention has been described for illustrative purposes, those skilled in the art will appreciate that various modifications, additions and substitutions are possible, without departing from the scope and spirit of the invention as disclosed in the accompanying claims.

What is claimed is:

1. A thermoelectric material for intermediate- and low-temperature applications, comprising a Ag-containing metallic thermoelectric material or semiconductor thermoelectric material and any one or a mixture of two or more selected from among La, Sc and MM.

2. The thermoelectric material of claim 1, wherein the metallic thermoelectric material is a chalcogenide-based thermoelectric material.

3. The thermoelectric material of claim 2, wherein the chalcogenide-based thermoelectric material is a Bi- or Pb-based thermoelectric material.

4. The thermoelectric material of claim 3, wherein the chalcogenide-based thermoelectric material further include any one or a mixture of two or more selected from among Fe, Cu, Ni, Al, Au, Pt, Cr, Zn and Sn.

5. The thermoelectric material of claim 1, wherein the semiconductor thermoelectric material is a Si-based thermoelectric material.
